(19) United States
(12) Patent Application Publication
(10) Pub. No.: US 2026/0129768 A1
(43) Pub. Date: May 7, 2026

(54) FLIPPING DEVICE AND ELECTROPLATING PRODUCTION LINE

(71) Applicant: UNIVERSAL CIRCUIT BOARD EQUIPMENT CO., LTD., Dongguan (CN)

(72) Inventor: Takwo CHAN, Dongguan (CN)

(73) Assignee: UNIVERSAL CIRCUIT BOARD EQUIPMENT CO., LTD., Dongguan (CN)

(21) Appl. No.: 19/031,088

(22) Filed: Jan. 17, 2025

(30) Foreign Application Priority Data
Nov. 4, 2024 (CN) 202411560904.X

(51) Int. Cl. H05K 3/18

(52) U.S. Cl. CPC H05K 3/188; H05K 2203/0165; H05K 2203/0723; H05K 2203/1554; H05K 2203/1572

(57) ABSTRACT

Disclosed are a flipping device and an electroplating production line. The flipping device is applied to the electroplating production line. The electroplating production line includes two horizontal electroplating devices. The flipping device is provided between the two horizontal electroplating devices. The flipping device includes a frame, a feeding mechanism and a flipping mechanism provided on the frame. The feeding mechanism includes a first horizontal surface at one end close to the first horizontal electroplating device, and a second horizontal surface is provided at one end close to the second horizontal electroplating device. The first horizontal surface is configured to receive the circuit board from the first horizontal electroplating device after electroplating, and the feeding mechanism conveys the circuit board to the second horizontal surface. The flipping mechanism is configured to flip the circuit board on the feeding mechanism.

### CROSS-REFERENCE TO RELATED APPLICATIONS

This application claims priority to Chinese Patent Application No. 202411560904.X, filed on Nov. 4, 2024, the entire contents of which are incorporated herein by reference.

### TECHNICAL FIELD

The present application relates to the technical field of circuit board electroplating, and in particular to a flipping device and an electroplating production line.

### BACKGROUND

In the related art, the effect of electroplating the printed circuit board (PCB) once is not very ideal, and secondary and tertiary electroplating are required. The primary and secondary electroplating will plate thinner, but the surface of the board is required to be plated very evenly, so the primary and secondary electroplating adopts a horizontal electroplating method. In order to achieve the best electroplating effect, the board will be flipped and the clamping point edge will be replaced. Because the current close to the clamping point edge is large and the plating will generally be thicker. The board is flipped because the chemical environment of the upper and lower board surfaces is different. After the existing flipping device is flipped, the positioning accuracy of the board is low, the turning step is slow and cumbersome, the efficiency is not high, and the quality of the circuit board electroplating is affected.

### SUMMARY

The main purpose of the present application is to provide a flipping device and an electroplating production line, aiming to solve the problem that the electroplating quality of existing circuit boards is poor.

To achieve the above purpose, the present application provides a flipping device, applied to an electroplating production line.

In an embodiment, the flipping device includes a frame, a feeding mechanism provided on the frame, and a flipping mechanism provided on the frame. The electroplating production line includes two horizontal electroplating devices, the horizontal electroplating device includes an electroplating conveying mechanism and an electroplating tank, the electroplating conveying mechanism is configured to clamp a side of a circuit board and drive the circuit board to move in the electroplating tank for electroplating, the flipping device is provided between the two horizontal electroplating devices.

In an embodiment, the two horizontal electroplating devices includes a first horizontal electroplating device and a second horizontal electroplating device, the feeding mechanism is provided with a first horizontal surface at one end close to the first horizontal electroplating device, and a second horizontal surface is provided at one end close to the second horizontal electroplating device.

In an embodiment, the first horizontal surface is configured to receive the circuit board from the first horizontal electroplating device after electroplating, the feeding mechanism conveys the circuit board to the second horizontal surface, enabling the circuit board to enter the second horizontal electroplating device horizontally from the second horizontal surface.

In an embodiment, the flipping mechanism is configured to flip the circuit board on the feeding mechanism, enabling the electroplating conveying mechanisms of the two horizontal electroplating devices to clamp opposite sides of the circuit board respectively.

In an embodiment, the flipping mechanism includes a driving component, a rotating shaft and a clamping component, the clamping component is provided on the rotating shaft, the rotating shaft is drivingly connected to the driving component, the clamping component is provided with a slot for inserting the circuit board, and the driving component is configured to drive the rotating shaft to rotate, enabling the clamping component to drive the circuit board to flip.

In an embodiment, the clamping component includes a plurality of clamping blocks, the plurality of clamping blocks are provided at intervals along a length direction of the rotating shaft; each clamping block is provided with a groove, and a plurality of grooves are assembled together to form the slot.

In an embodiment, the clamping component further includes a plurality of first guide wheels, and the plurality of first guide wheels are provided at intervals on the rotating shaft and are provided at a bottom of the groove to slide against a side of the circuit board; and/or a plurality of the clamping blocks and a plurality of the first guide wheels are respectively provided on opposite sides of the rotating shaft.

In an embodiment, the driving component includes a driving motor, a transmission belt and a transmission wheel, one end of the rotating shaft is connected to the transmission wheel, the transmission belt is sleeved on the transmission wheel and the driving motor, and the driving motor is configured to drive the transmission wheel to rotate through the transmission belt to drive the rotating shaft to rotate.

In an embodiment, the feeding mechanism includes a first conveying line and a second conveying line provided at intervals, the first conveying line and the second conveying line are configured to transport the circuit board along a first direction, and the flipping mechanism is provided between the first conveying line and the second conveying line to flip a circuit board on the first conveying line to the second conveying line.

In an embodiment, the feeding mechanism further includes a first pushing component and a second pushing component, the first pushing component is provided on the first conveying line to push the circuit board on the first conveying line to the flipping mechanism, and the second pushing component is provided on the second conveying line to push a circuit board on the second conveying line to move along the first direction.

In an embodiment, the feeding mechanism further includes a third conveying line and a fourth conveying line; the fourth conveying line is extended along a conveying direction of the first conveying line, the second pushing component is configured to push the circuit board on the second conveying line to the third conveying line, the third conveying line is provided along a second direction for transporting the circuit board on the second conveying line to the fourth conveying line, and the first direction forms an angle with the second direction; and/or the third conveying line is connected with the second conveying line and the fourth conveying line, and is raised and lowered along a third direction to lift the circuit board on the second conveying line or lower a circuit board on the third conveying line to the fourth conveying line.

In an embodiment, the feeding mechanism further includes a third pushing component and a fourth pushing component; the third pushing component is provided on the third conveying line to push the circuit board on the third conveying line to the fourth conveying line along the second direction, and the fourth pushing component is configured to push the circuit board on a fourth conveying line along the first direction and adjust a spacing between two adjacent circuit boards; and/or the feeding mechanism further includes a positioning component, the positioning component is provided on the fourth conveying line, the third pushing component is configured to push the circuit board on the third conveying line to move along the second direction and abut against the positioning component.

The present application further provides an electroplating production line, including: two horizontal electroplating devices, and the flipping device as described above. The flipping device is provided between the two horizontal electroplating devices.

The technical solution of the present application connects two horizontal electroplating devices by using a flipping device to improve the electroplating quality and production efficiency of the circuit board. Specifically, the flipping device is applied to an electroplating production line, and the electroplating production line includes two horizontal electroplating devices. The horizontal electroplating device includes an electroplating conveying mechanism and an electroplating tank. The electroplating conveying mechanism is configured to clamp one side of the circuit board and drive the circuit board to move in the electroplating tank for electroplating. The flipping device is provided between the two horizontal electroplating devices. The flipping device includes a frame and a feeding mechanism and a flipping mechanism provided on the frame. The feeding mechanism includes a conveying track, and the conveying track includes a first horizontal surface and a second horizontal surface for conveying the circuit board. After the electroplating of one horizontal electroplating device is completed, the circuit board enters the first horizontal surface, and the feeding mechanism sends it to the second horizontal surface, so that the circuit board enters the second horizontal electroplating device horizontally. During the conveying process, the flipping mechanism flips the circuit board, and swaps the two sides of the opposite sides of the circuit board, so that the electroplating conveying mechanisms of the two horizontal electroplating devices clamp the opposite sides of the circuit board respectively.

It should be noted that horizontal electroplating device generally energizes the clamps of the electroplating conveying mechanism to electroplate the circuit board. The current on the circuit board close to the clamping point of the clamp of the electroplating conveying mechanism is large, so the plating is relatively thicker. The farther the position of the circuit board is from the clamp of the electroplating conveying mechanism, the smaller the current is, and the plating is relatively thinner. A single electroplating obviously cannot achieve a uniform plating effect, and the upper and lower surfaces of the circuit board in the electroplating tank are in different chemical solution environments, so the electroplating effects on both sides are also different. This solution sets a flipping device to flip the upper and lower surfaces of the circuit board and switch the clamping point to the opposite side, so that the circuit board is more uniformly plated after being electroplated twice by two horizontal electroplating devices, effectively improving the production quality of the circuit board.

### BRIEF DESCRIPTION OF THE DRAWINGS

In order to more clearly illustrate the embodiments of the present application or the technical solutions in the related art, the drawings required for use in the embodiments or the description of the related art will be briefly introduced below. Obviously, the drawings described below are only some embodiments of the present application. For those skilled in the art other drawings can be obtained based on the structures shown in these drawings without creative work.

FIG. 1 is a schematic structural view of a flipping device according to an embodiment of the present application.

FIG. 2 is a schematic internal structural view of the flipping device according to an embodiment of the present application.

FIG. 3 is a schematic structural view of an assembly structure of a feeding mechanism and a flipping mechanism in the flipping device according to an embodiment of the present application.

FIG. 4 is a schematic partial structural view of the feeding mechanism and the flipping mechanism in the flipping device according to an embodiment of the present application.

FIG. 5 is a schematic structural view of the feeding mechanism in the flipping device when transporting a circuit board according to an embodiment of the present application.

FIG. 6 is a schematic structural view of the flipping mechanism in the flipping device according to an embodiment of the present application.

FIG. 7 is a schematic structural view of a rotating shaft and the clamping component in the flipping device according to an embodiment of the present application.

FIG. 8 is a schematic structural view of a first pushing component in the flipping device according to an embodiment of the present application.

FIG. 9 is a schematic partial structural view of an electroplating production line according to an embodiment of the present application.

The realization of the objective, functional characteristics, and advantages of the present application are further described with reference to the accompanying drawings.

### DETAILED DESCRIPTION OF THE EMBODIMENTS

The technical solutions of the embodiments of the present application will be described in more detail below with reference to the accompanying drawings. It is obvious that the embodiments to be described are only some rather than all of the embodiments of the present application. All other embodiments obtained by those skilled in the art based on the embodiments of the present application without creative efforts shall fall within the scope of the present application.

It should be noted that if there is a directional indication (such as up, down, left, right, front, rear) in the embodiments of the present application, the directional indication is only configured to explain the relative positional relationship, movement, etc. of the components in a certain posture (as shown in the drawings). If the specific posture changes, the directional indication will change accordingly.

Besides, the descriptions associated with, e.g., “first” and “second,” in the present application are merely for descriptive purposes, and cannot be understood as indicating or suggesting relative importance or impliedly indicating the number of the indicated technical feature. Therefore, the feature associated with “first” or “second” can expressly or impliedly include at least one such feature. The meaning of “and/or” appearing in the present application includes three parallel scenarios. For example, “A and/or B” includes only A, or only B, or both A and B. In addition, the technical solutions between the various embodiments can be combined with each other, but they must be based on the realization of those skilled in the art. When the combination of technical solutions is contradictory or cannot be achieved, it should be considered that such a combination of technical solutions does not exist, nor is it within the scope of the present application.

In the related art, the effect of electroplating the printed circuit board (PCB) once is not very ideal, and secondary and tertiary electroplating are required. The primary and secondary electroplating will plate thinner, but the surface of the board is required to be plated very evenly, so the primary and secondary electroplating adopts a horizontal electroplating method. In order to achieve the best electroplating effect, the board will be flipped and the clamping point edge will be replaced. Because the current close to the clamping point edge is large and the plating will generally be thicker. The board is flipped because the chemical environment of the upper and lower board surfaces is different. After the existing flipping device is flipped, the positioning accuracy of the board is low, the turning step is slow and cumbersome, the efficiency is not high, and the quality of the circuit board electroplating is affected.

The present application provides a flipping device.

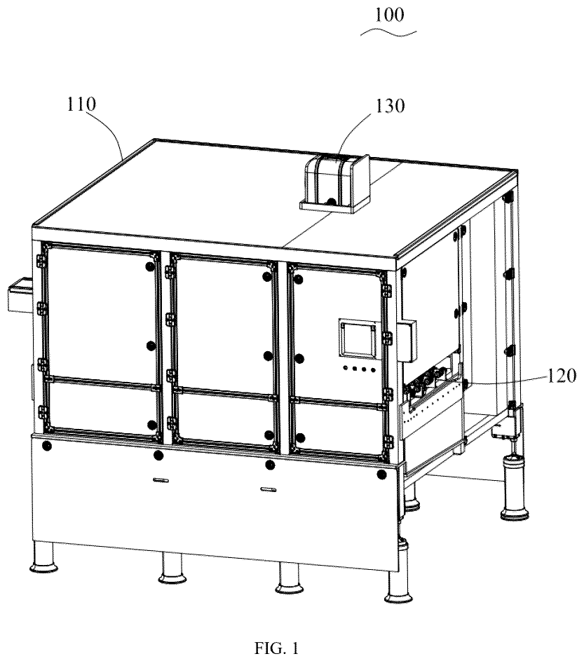

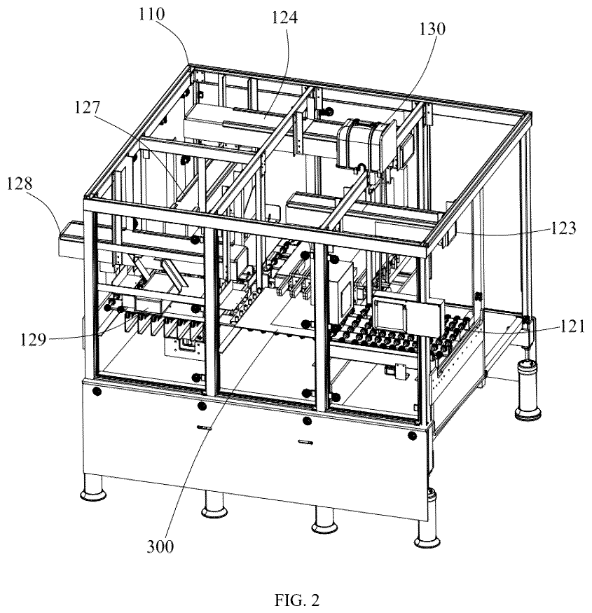

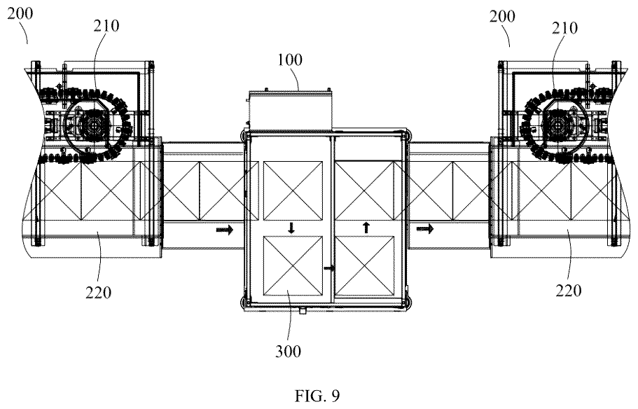

As shown in FIG. 1, FIG. 2 and FIG. 9, in an embodiment of the present application, the flipping device 100 is applied to an electroplating production line, and the electroplating production line includes two horizontal electroplating devices 200. The horizontal electroplating device 200 includes an electroplating conveying mechanism 210 and an electroplating tank 220. The electroplating conveying mechanism 210 is configured to clamp one side of the circuit board 300 and drive the circuit board 300 to move in the electroplating tank 220 for electroplating. The flipping device 100 is provided between the two horizontal electroplating devices 200. The flipping device 100 includes a frame 110, a feeding mechanism 120 provided on the frame 110 and a flipping mechanism 130 provided on the frame 110. The feeding mechanism 120 includes a conveying track, and the conveying track includes a first horizontal surface and a second horizontal surface for horizontally placing the circuit board 300. The two horizontal electroplating devices 200 includes a first horizontal electroplating device 200 and a second horizontal electroplating device 200. As shown in FIG. 9, the first horizontal surface is aligned with the board outlet end of the first horizontal electroplating device 200, and the second horizontal surface is aligned with the board inlet end of the second horizontal electroplating device 200. After the circuit board 300 is electroplated by one of the horizontal electroplating devices 200, it enters the first horizontal surface, and the feeding mechanism 120 feeds it to the second horizontal surface, so that the circuit board 300 enters the second horizontal electroplating device 200 horizontally. During the conveying process, the flipping mechanism 130 flips the circuit board 300 on the feeding mechanism 120, and swaps the positions of the two sides of the opposite sides of the circuit board 300, so that the electroplating conveying mechanisms 210 of the two horizontal electroplating devices 200 clamp the opposite sides of the circuit board 300 respectively.

It should be noted that the horizontal electroplating device 200 generally energizes the clamp of the electroplating conveying mechanism 210 to electroplate the circuit board 300. The current on the circuit board 300 close to the clamping point of the clamp of the electroplating conveying mechanism 210 is large, so the plating is relatively thicker. The farther the position of the circuit board 300 is from the clamp of the electroplating conveying mechanism 210, the smaller the current is, and the plating is relatively thinner. A single electroplating cannot achieve a uniform plating effect. The upper and lower surfaces of the circuit board 300 in the electroplating tank 220 are in different chemical solution environments, so the electroplating effects on both sides are also different. This solution sets a flipping device 100 to flip the upper and lower surfaces of the circuit board 300 and switch the clamping point to the opposite side, so that the circuit board 300 is more uniformly plated after being electroplated twice by the two horizontal electroplating devices 200, effectively improving the production quality of the circuit board 300.

The horizontal conveying surface of the feeding mechanism 120 can be formed by structures such as a belt conveying line, a roller conveying line, and a roller friction wheel conveying line. The circuit board 300 moves horizontally from the previous horizontal electroplating device 200 to the electroplating conveying mechanism 210 of the next horizontal electroplating device 200 on the feeding mechanism 120, so that the electroplating conveying mechanism 210 can accurately clamp the circuit board 300 to ensure the stability of the docking and transportation process. The quantity of conveying lines can be multiple or single, and the conveying line can be a completely horizontal conveying surface. At this time, the first horizontal surface and the second horizontal surface are provided coplanar with the horizontal conveying surface. Or a curved and undulating conveying structure is provided between the first horizontal surface and the second horizontal surface. It is necessary to ensure that the circuit board 300 enters the first horizontal surface horizontally from the board outlet end of the horizontal electroplating device 200, or enters the board inlet end of the next horizontal electroplating device 200 horizontally from the second horizontal surface. There is no specific restriction on the quantity of conveying lines and the structure between the two horizontal surfaces, and the circuit board 300 can be accurately conveyed.

In an embodiment, the flipping mechanism 130 includes a driving component 131, a rotating shaft 132, and a clamping component 133. The clamping component 133 is provided on the rotating shaft 132, and the rotating shaft 132 is drivingly connected to the driving component 131. The clamping component 133 is provided with a slot 133a for inserting the circuit board 300. The driving component 131 is configured to drive the rotating shaft 132 to rotate, so that the clamping component 133 drives the circuit board 300 to flip.

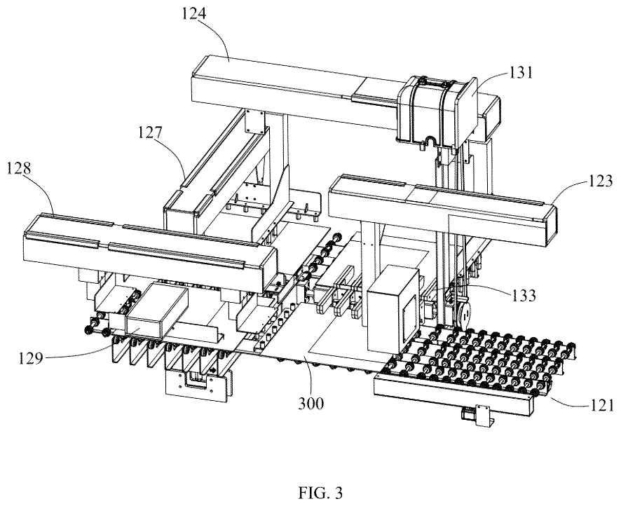

As shown in FIG. 3 to FIG. 7, in an embodiment of the present application, the flipping mechanism 130 includes a driving component 131, a rotating shaft 132 and a clamping component 133. The feeding mechanism 120 transports the circuit board 300 along the first direction. The rotating shaft 132 is also extended along the first direction. The clamping component 133 is provided on the rotating shaft 132. The driving component 131 is configured to drive the rotating shaft 132 and the clamping component 133 to rotate. The clamping component 133 is provided with a slot 133a, which extends along the axial direction of the rotating shaft 132 and can be aligned with the horizontal conveying surface of the feeding mechanism 120. When the feeding mechanism 120 transports the circuit board 300 to the flipping mechanism 130, the side of the circuit board 300 is inserted into the slot 133a, the driving component 131 drives the rotating shaft 132 to rotate, and the clamping component 133 flips the circuit board 300 180° and puts it back on the horizontal conveying surface of the feeding mechanism 120. At this time, the circuit board 300 is flipped over, and the two sides of the circuit board 300 along the first direction are swapped, so that the sides of the circuit board 300 clamped by the electroplating conveying mechanism 210 in the two horizontal electroplating devices 200 can be evenly plated.

In an embodiment, the clamping component 133 includes a plurality of clamping blocks 1331, which are provided at intervals along the length direction of the rotating shaft 132, and each clamping block 1331 is provided with a groove 1332, and the plurality of grooves 1332 are assembled together to form the slot 133a.

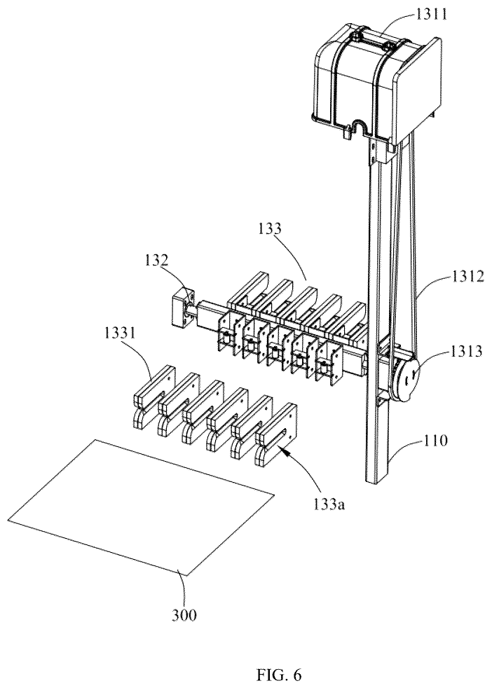

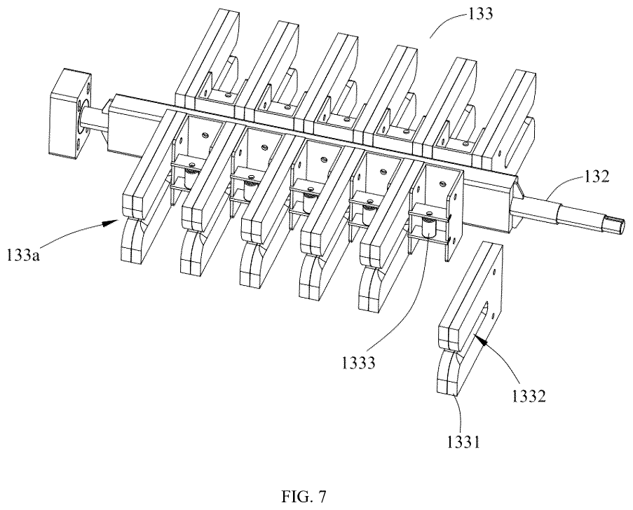

As shown in FIG. 6 and FIG. 7, in an embodiment of the present application, the clamping component 133 includes a plurality of clamping blocks 1331. The plurality of clamping blocks 1331 are provided at intervals along the axial direction of the rotating shaft 132. A groove 1332 is provided on each clamping block 1331. The groove 1332 is opened in a direction away from the rotating shaft 132. The plurality of grooves 1332 are assembled together to form the slot 133a. When the circuit board 300 moves from the horizontal conveying surface, one side of the circuit board 300 passes through the grooves 1332 of the plurality of clamping blocks 1331 in sequence. When the preset position is reached, the driving component 131 drives the rotating shaft 132 to rotate. The clamping block 1331 clamps the circuit board 300 and rotates 180° around the rotating shaft 132 above the horizontal conveying surface. When the slot 133a is aligned with the horizontal conveying surface again, the feeding mechanism 120 conveys the circuit board 300 to the next horizontal electroplating device 200 in the horizontal direction. It is understandable that a plurality of clamping blocks 1331 are provided to form the slot 133a. For circuit boards 300 of different sizes, the length of the slot 133a can be adjusted by adjusting the quantity of clamping blocks 1331 or the spacing between adjacent clamping blocks 1331, so that circuit boards 300 of different specifications can be flipped, which is highly practical.

In an embodiment, the clamping component 133 further includes a plurality of first guide wheels 1333, which are provided at intervals on the rotating shaft 132 and provided at the bottom of the groove 1332, so as to slide against the side of the circuit board 300; and/or, a plurality of clamping blocks 1331 and a plurality of first guide wheels 1333 are respectively provided on opposite sides of the rotating shaft 132.

As shown in FIG. 6 and FIG. 7, in an embodiment of the present application, the clamping component 133 also includes a plurality of first guide wheels 1333. The plurality of guide wheels are provided at intervals along the axial direction of the rotating shaft 132, and a guide wheel is provided between two adjacent blocks 1331. The side wall of the guide wheel is higher than the bottom wall of the groove 1332. When the circuit board 300 is moved along the first direction and inserted into the slot 133a, the side of the circuit board 300 can slide and abut against the side wall of the first guide wheel 1333 to reduce friction. During the flipping process, due to the action of gravity, the side of the circuit board 300 is abutted against the side wall of the plurality of first guide wheels 1333. When the flipping is completed, the feeding mechanism 120 conveys the circuit board 300 along the horizontal conveying surface, and the side of the circuit board 300 slides and is abutted against the plurality of first guide wheels 1333 to reduce friction and avoid wear of the circuit board 300. The arrangement of the first guide wheel 1333 is not limited to this embodiment, and there are other structures, such as setting a first guide wheel 1333 between two or three blocks 1331 to prevent the circuit board 300 from getting stuck or worn. This is not specifically limited here.

In order to improve the flipping efficiency, a plurality of clamping blocks 1331 and a plurality of first guide wheels 1333 are respectively set on the opposite sides of the rotating shaft 132. The plurality of blocks 1331 and the plurality of first guide wheels 1333 are provided on opposite sides of the rotating shaft 132 in a mirror-like manner to form two slots 133a. When the first circuit board 300 enters the first slot 133a and completes the flipping, the second circuit board 300 can enter the second slot 133a and wait for flipping. When the first circuit board 300 moves out of the slot 133a along the first direction, the second circuit board 300 can be flipped, and the third circuit board 300 subsequently enters the slot 133a and waits. The cycle continues like this. The rotating shaft 132 only needs to flip half a circle each time. By utilizing the interval time of transportation after the flipping of the circuit board 300, the transportation efficiency of the entire flipping device 100 can be greatly improved.

In an embodiment, the driving component 131 includes a driving motor 1311, a transmission belt 1312, and a transmission wheel 1313. One end of the rotating shaft 132 is connected to the transmission wheel 1313. The transmission belt 1312 is sleeved on the transmission wheel 1313 and the driving motor 1311. The driving motor 1311 is configured to drive the transmission wheel 1313 to rotate through the transmission belt 1312 to drive the rotating shaft 132 to rotate.

As shown in FIG. 6, in an embodiment of the present application, the driving component 131 includes a driving motor 1311, a transmission belt 1312, and a transmission wheel 1313. One end of the rotating shaft 132 is connected to the transmission wheel 1313. The driving motor 1311 is set on a bracket and connected to the transmission wheel 1313 through the transmission belt 1312. The driving motor 1311 drives the transmission wheel 1313 to rotate through the transmission belt 1312, so that the transmission wheel 1313 drives the rotating shaft 132 to rotate along the first direction and drives the clamping component 133 to flip the circuit board 300. The cost of the drive motor 1311 and the transmission belt 1312 is lower than that of the gears, and the transmission belt 1312 can absorb vibration and reduce noise, making it quieter than gears and more convenient and simple to maintain. In other embodiments of the present application, the structure of the drive component 131 is not specifically limited.

In an embodiment, the feeding mechanism 120 includes a first conveying line 121 and a second conveying line 122 provided at intervals, and the first conveying line 121 and the second conveying line 122 is configured to transport the circuit board 300 along a first direction, and the flipping mechanism 130 is provided between the first conveying line 121 and the second conveying line 122 to flip the circuit board 300 on the first conveying line 121 to the second conveying line 122.

As shown in FIG. 3 to FIG. 5, in an embodiment of the present application, the feeding mechanism 120 includes a first conveying line 121 and a second conveying line 122. The first conveying line 121 and the second conveying line 122 are provided at intervals and both extended along the first direction. The flipping mechanism 130 is provided between the first conveying line 121 and the second conveying line 122. It should be noted that in this embodiment, the first conveying line 121 and the second conveying line 122 form a horizontal conveying surface by setting a friction wheel on the roller. The rotation of the roller drives the friction wheels to rotate, and the friction wheels drive the circuit board 300 to move along the first direction. The clamping block 1331 of the clamping component 133 is set in the gap between the rollers. The circuit board 300 moves along the first direction on the first conveying line 121 and is inserted into the slot 133a. The flipping mechanism 130 drives the circuit board 300 to rotate and flips the circuit board 300 to the second conveying line 122. When the slot 133a is aligned with the horizontal conveying surface of the second conveying line 122, the second conveying line 122 drives the circuit board 300 to continue to move along the first direction and disengage from the flipping mechanism 130. At this time, the rotating shaft 132 can flip the next circuit board 300 again.

It can be understood that the end of the first conveying line 121 away from the flipping mechanism 130 can be connected to the board outlet end of one of the horizontal electroplating device 200, and the end of the second conveying line 122 away from the flipping mechanism 130 can be connected to the board inlet end of the second horizontal electroplating device 200. At this time, the two horizontal electroplating devices 200 are not on the same horizontal line, or as shown in FIG. 9, when the two horizontal electroplating devices 200 are aligned, an additional conveying structure needs to be connected to the second conveying line 122 to transport the flipped circuit board 300 to the next horizontal electroplating device 200. This structure is explained in detail below.

In an embodiment, the feeding mechanism 120 further includes a first pushing component 123 and a second pushing component 124. The first pushing component 123 is provided on the first conveying line 121 to push the circuit board 300 on the first conveying line 121 to the flipping mechanism 130. The second pushing component 124 is provided on the second conveying line 122 to push the circuit board 300 on the second conveying line 122 to move along the first direction.

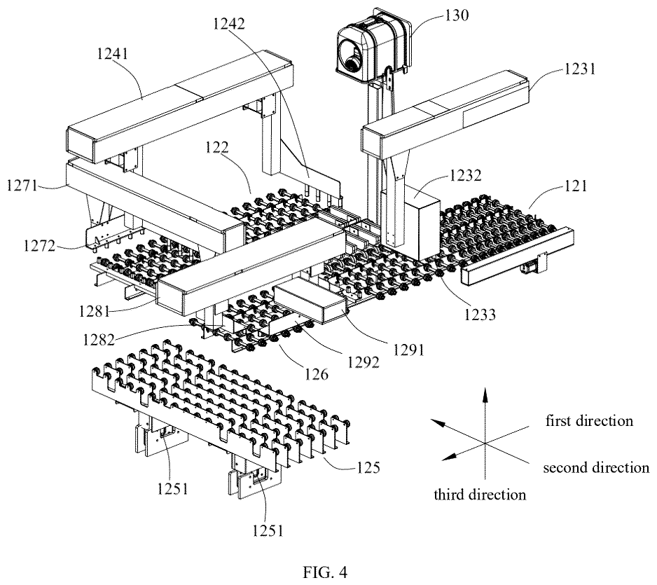

As shown in FIG. 3 and FIG. 4, in an embodiment of the present application, the feeding mechanism 120 further includes a first pushing component 123 and a second pushing component 124. The first pushing component 123 includes a first linear motor 1231 and a first push plate 1233 provided above the first conveying line 121. The first linear motor 1231 is provided along the first direction. The first push plate 1233 and the first linear motor 1231 are drivingly connected to push the circuit board 300 on the first conveying line 121 along the first direction and insert one side of the circuit board 300 into the slot 133a of the flipping mechanism 130. The second pushing component 124 includes a second linear motor 1241 and a second push plate 1242 provided above the second conveying line 122. The second linear motor 1241 is provided along the first direction. The second push plate 1242 and the second linear motor 1241 are drivingly connected to push the flipped circuit board 300 on the second conveying line 122 out of the slot 133a of the flipping mechanism 130 along the first direction.

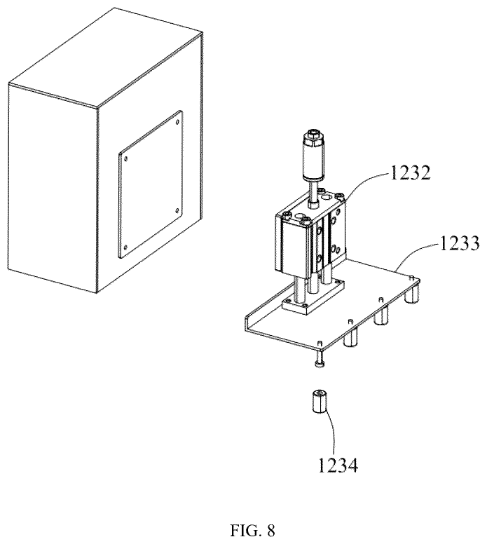

The first pushing component 123 and the second pushing component 124 are provided to improve the conveying efficiency of the circuit board 300. It should be noted that, as shown in FIG. 8, the first pushing component 123 also includes a first lifting mechanism 1232 and a second guide wheel 1234. The first push plate 1233 is connected to the first linear motor 1231 through the first lifting mechanism 1232. The first lifting mechanism 1232 adopts a cylinder, which can drive the first push plate 1233 to move up and down along the third direction. A plurality of second guide wheels 1234 are provided on the side of the first push plate 1233 facing the first conveying line 121. The plurality of second guide wheels 1234 are provided at intervals along the second direction and are rotatably provided on the first push plate 1233. When the circuit board 300 electroplated by the horizontal electroplating device 200 enters the first conveying line 121 from the board outlet end, and the first lifting mechanism 1232 drives the first push plate 1233 away from the first conveying line 121. The first linear motor 1231 drives the first push plate 1233 to move away from the flipping device 100. After reaching the predetermined position, the first lifting mechanism 1232 drives the first push plate 1233 to move downward along the third direction so that the side wall of the second guide wheel 1234 can abut against the circuit board 300. At this time, the first linear motor 1231 drives the first push plate 1233 to move along the first direction to drive the circuit board 300 to move and insert the circuit board 300 into the slot 133a of the flipping mechanism 130. As can be seen from the above, by setting the first lifting mechanism 1232, the interference between the first push plate 1233 and the circuit board 300 during the back and forth movement can be avoided.

In an embodiment, the feeding mechanism 120 further includes a third conveying line 125 and a fourth conveying line 126. The fourth conveying line 126 is extended along a conveying direction of the first conveying line 121, the second pushing component 124 is configured to push the circuit board 300 on the second conveying line 122 to the third conveying line 125, the third conveying line 125 is provided along a second direction for transporting the circuit board 300 on the second conveying line 122 to the fourth conveying line 126, and the first direction forms an angle with the second direction; and/or, the third conveying line 125 is connected with the second conveying line 122 and the fourth conveying line 126, and can be raised and lowered along a third direction, so as to be raised to lift the circuit board 300 on the second conveying line 122 or lower the circuit board 300 on the third conveying line 125 to the fourth conveying line 126.

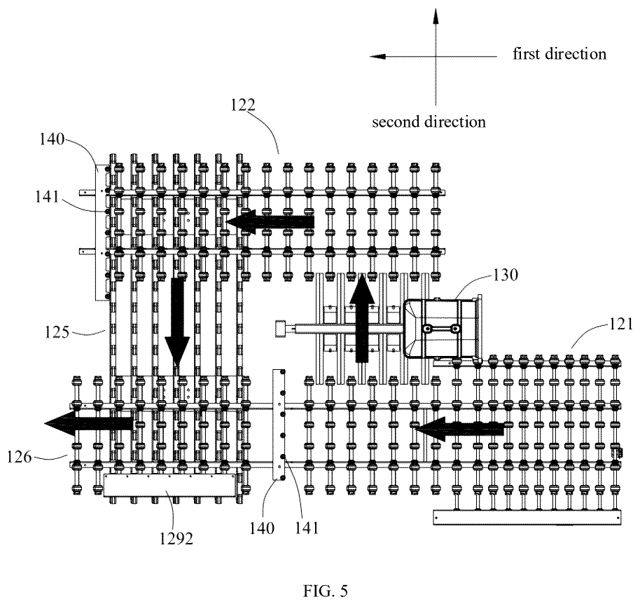

As shown in FIG. 3 and FIG. 4, in an embodiment of the present application, the feeding mechanism 120 further includes a third conveying line 125 and a fourth conveying line 126. The fourth conveying line 126 is provided on the extension line of the first conveying line 121. The third conveying line 125 is provided along the second direction and its two ends are respectively connected to the second conveying line 122 and the fourth conveying line 126. When the second pushing component 124 pushes the circuit board 300 on the second conveying line 122 to the third conveying line 125, the circuit board 300 can be moved on the third conveying line 125 in the opposite direction of the second direction to the fourth conveying line 126. Finally, the circuit board 300 is transported to the target horizontal electroplating device 200 along the first direction through the fourth conveying line 126. As shown in FIG. 5 and FIG. 9, the two horizontal electroplating devices 200 are aligned. This solution sets the third conveying line 125 and the fourth conveying line 126 so that the flipped circuit board 300 can be accurately transported to the corresponding horizontal electroplating device 200.

In an embodiment, the fourth conveying line 126 also adopts a structure in which a friction wheel is provided on a roller, while the third conveying line 125 adopts a bracket and a plurality of scroll wheels are provided on the bracket, and the plurality of scroll wheels are provided at intervals along the second direction. A second lifting mechanism 1251 is provided below the bracket, and the second lifting mechanism 1251 is configured to drive the bracket and the scroll wheels on the bracket to rise or fall along the third direction. When the circuit board 300 on the second conveying line 122 is transported to the position of the third conveying line 125, the second lifting mechanism 1251 drives the bracket to rise and lift the circuit board 300 located on the second conveying line 122. The circuit board 300 slides in contact with the scroll wheel on the third conveying line 125, and when the circuit board 300 moves in the opposite direction of the second direction to the position of the fourth conveying line 126, the second lifting mechanism 1251 drives the bracket to move downward along the third direction to place the circuit board 300 on the fourth conveying line 126. The fourth conveying line 126 is configured to transport the circuit board 300 to the corresponding horizontal electroplating device 200.

It is understandable that by setting the third conveying line 125 to rise and fall, and correspondingly setting scroll wheels spaced apart from the second conveying line 122 and the fourth conveying line 126, scratches on the circuit board 300 during movement can be avoided, thereby ensuring the electroplating quality of the circuit board 300.

In an embodiment, the feeding mechanism 120 further includes a third pushing component 127 and a fourth pushing component 128. The third pushing component 127 is provided on the third conveying line 125 to push the circuit board 300 on the third conveying line 125 to the fourth conveying line 126 along the second direction, and the fourth pushing component 128 is configured to push the circuit board 300 on the fourth conveying line 126 along the first direction and adjust a spacing between two adjacent circuit boards 300; and/or, the feeding mechanism 120 further includes a positioning component 129, the positioning component 129 is provided on the fourth conveying line 126, and the third pushing component 127 is configured to push the circuit board 300 on the third conveying line 125 to move along the second direction and abut against the positioning component 129.

As shown in FIG. 3 and FIG. 4, in an embodiment of the present application, the feeding mechanism 120 further includes a third pushing component 127 and a fourth pushing component 128. The third pushing component 127 includes a third linear motor 1271 provided along the second direction and a third push plate 1272 drivingly connected to the third linear motor 1271. When the third conveying line 125 lifts the circuit board 300 on the second conveying line 122, the third linear motor 1271 is configured to drive the third push plate 1272 to push the circuit board 300 to move above the fourth conveying line 126 along the opposite direction of the second direction. The fourth pushing component 128 includes a fourth linear motor 1281 provided along the first direction and a fourth push plate 1282 drivingly connected to the fourth linear motor 1281. When the third conveying line 125 places the circuit board 300 on the fourth conveying line 126, the fourth linear motor 1281 drives the fourth push plate 1282 to push the circuit board 300 to the horizontal electroplating device 200 along the first direction.

It should be noted that a plurality of second guide wheels 1234 are provided below the second push plate 1242, the third push plate 1272 and the fourth push plate 1282 at intervals corresponding to the side of the circuit board 300, so as to push the circuit board 300 to move.

In an embodiment, the feeding mechanism 120 also includes a positioning component 129. The positioning component 129 includes a fifth linear motor 1291 provided above the fourth conveying line 126 and a stopper 1292 drivingly connected to the fifth linear motor 1291. When the third linear motor 1271 pushes the circuit board 300 on the third conveying line 125 to reach above the fourth conveying line 126, it is abutted against the stopper 1292 for positioning, so that the side of the circuit board 300 is aligned with the electroplating conveying mechanism 210 of the horizontal electroplating device 200, thereby ensuring the stability of the clamping. The fifth linear motor 1291 is configured to drive the stopper 1292 to move to adjust the position of the stopper 1292, so as to ensure the position accuracy of the circuit board 300.

It should be noted that, in addition to the stopper 1292, the feeding mechanism 120 also includes a plurality of limiting members 140. As shown in FIG. 5, the limiting members 140 are respectively provided at the position of the first conveying line 121 close to the flipping mechanism 130 and the position of the second conveying line 122 close to the third conveying line 125, so as to position the circuit board 300 on the first conveying line 121 and the second conveying line 122. A third guide wheel 141 is provided on the limiting member 140 and/or the stopper 1292. The third guide wheel 141 has the same structure as the first guide wheel 1333 and the second guide wheel 1234 mentioned above. Both limiting members 140 are provided along the second direction and a plurality of third guide wheels 141 on the limiting member 140 are also provided at intervals along the second direction, so as to guide the circuit board 300. A plurality of third guide wheels 141 are also provided on the side of the stopper 1292 facing the fourth conveying line 126 and are provided at intervals along the first direction to abut against and position the circuit board 300, and guide the circuit board 300 when it moves along the first direction.

In an embodiment, since the fourth linear motor 1281 and the fourth push plate 1282 push the circuit board 300 to move, the fourth linear motor 1281 can be configured to adjust the spacing of the positioned circuit boards 300, and a spacing between two adjacent circuit boards 300 entering the horizontal electroplating device 200 is set to a preset value L. However, due to the influence of the control accuracy of the mechanical transmission, there is a discrepancy between the actual spacing value D and the preset value L between two adjacent circuit boards. By setting the linear motor, L and D meet: L−1.5mm≤D≤L+1.5mm. That is, the error can be controlled within the range of 1.5 mm. For example, if the preset value L between the boards is set to 10 mm, then the minimum value of the actual spacing value D can be 8.5 mm, the maximum value can be 11.5 mm, the spacing value D can also be 9.5 mm, or any value within the aforementioned range. Precisely controlling the spacing between two adjacent circuit boards 300 can improve electroplating quality.

The present application also provides an electroplating production line, the electroplating production line includes two horizontal electroplating devices 200 and a flipping device 100, the flipping device 100 is provided between the two horizontal electroplating devices 200, and the specific structure of the flipping device 100 refers to the above-mentioned embodiment. Since the horizontal electroplating device 200 adopts all the technical solutions of all the above-mentioned embodiments, it has at least all the beneficial effects brought by the technical solutions of the above-mentioned embodiments, which will not be described one by one here.

The above contents are only some embodiments of the present application, and do not limit the scope of the present application. All equivalent structural changes made by using the contents of the present application specification and drawings under the inventive concept of the present application, or directly/indirectly applied in other related technical fields are included in the scope of the present application.

What is claimed is:

1. A flipping device, applied to an electroplating production line, comprising:
a frame;
a feeding mechanism provided on the frame; and
a flipping mechanism provided on the frame;
wherein the electroplating production line comprises two horizontal electroplating devices, the horizontal electroplating device comprises an electroplating conveying mechanism and an electroplating tank, the electroplating conveying mechanism is configured to clamp a side of a circuit board and drive the circuit board to move in the electroplating tank for electroplating, the flipping device is provided between the two horizontal electroplating devices;
the two horizontal electroplating devices comprises a first horizontal electroplating device and a second horizontal electroplating device, the feeding mechanism is provided with a first horizontal surface at one end close to the first horizontal electroplating device, and a second horizontal surface is provided at one end close to the second horizontal electroplating device;
the first horizontal surface is configured to receive the circuit board from the first horizontal electroplating device after electroplating, the feeding mechanism conveys the circuit board to the second horizontal surface, enabling the circuit board to enter the second horizontal electroplating device horizontally from the second horizontal surface; and
the flipping mechanism is configured to flip the circuit board on the feeding mechanism, enabling the electroplating conveying mechanisms of the two horizontal electroplating devices to clamp opposite sides of the circuit board respectively.

2. The flipping device according to claim 1, wherein the flipping mechanism comprises a driving component, a rotating shaft and a clamping component, the clamping component is provided on the rotating shaft, the rotating shaft is drivingly connected to the driving component, the clamping component is provided with a slot for inserting the circuit board, and the driving component is configured to drive the rotating shaft to rotate, enabling the clamping component to drive the circuit board to flip.

3. The flipping device according to claim 2, wherein the clamping component comprises a plurality of clamping blocks, the plurality of clamping blocks are provided at intervals along a length direction of the rotating shaft; each clamping block is provided with a groove, and a plurality of grooves are assembled together to form the slot.

4. The flipping device according to claim 3, wherein:
the clamping component further comprises a plurality of first guide wheels, and the plurality of first guide wheels are provided at intervals on the rotating shaft and are provided at a bottom of the groove to slide against a side of the circuit board; and/or
a plurality of the clamping blocks and a plurality of the first guide wheels are respectively provided on opposite sides of the rotating shaft.

5. The flipping device according to claim 2, wherein the driving component comprises a driving motor, a transmission belt and a transmission wheel, one end of the rotating shaft is connected to the transmission wheel, the transmission belt is sleeved on the transmission wheel and the driving motor, and the driving motor is configured to drive the transmission wheel to rotate through the transmission belt to drive the rotating shaft to rotate.

6. The flipping device according to claim 1, wherein the feeding mechanism comprises a first conveying line and a second conveying line provided at intervals, the first conveying line and the second conveying line are configured to transport the circuit board along a first direction, and the flipping mechanism is provided between the first conveying line and the second conveying line to flip a circuit board on the first conveying line to the second conveying line.

7. The flipping device according to claim 6, wherein the feeding mechanism further comprises a first pushing component and a second pushing component, the first pushing component is provided on the first conveying line to push the circuit board on the first conveying line to the flipping mechanism, and the second pushing component is provided on the second conveying line to push a circuit board on the second conveying line to move along the first direction.

8. The flipping device according to claim 7, wherein:
the feeding mechanism further comprises a third conveying line and a fourth conveying line;
the fourth conveying line is extended along a conveying direction of the first conveying line, the second pushing component is configured to push the circuit board on the second conveying line to the third conveying line, the third conveying line is provided along a second direction for transporting the circuit board on the second conveying line to the fourth conveying line, and the first direction forms an angle with the second direction; and/or
the third conveying line is connected with the second conveying line and the fourth conveying line, and is raised and lowered along a third direction to lift the circuit board on the second conveying line or lower a circuit board on the third conveying line to the fourth conveying line.

9. The flipping device according to claim 8, wherein:
the feeding mechanism further comprises a third pushing component and a fourth pushing component;
the third pushing component is provided on the third conveying line to push the circuit board on the third conveying line to the fourth conveying line along the second direction, and the fourth pushing component is configured to push the circuit board on a fourth conveying line along the first direction and adjust a spacing between two adjacent circuit boards; and/or
the feeding mechanism further comprises a positioning component, the positioning component is provided on the fourth conveying line, the third pushing component is configured to push the circuit board on the third conveying line to move along the second direction and abut against the positioning component.

10. An electroplating production line, comprising:
two horizontal electroplating devices;
the flipping device according to claim 1,
wherein the flipping device is provided between the two horizontal electroplating devices.
